(19) United States
(12) Patent Application Publication
(10) Pub. No.: US 2026/0198025 A1
(43) Pub. Date: Jul. 9, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Takeshi SUWA, Kawasaki Kanagawa (JP); Tomoko MATSUDAI, Shibuya Tokyo (JP); Yoko IWAKAJI, Meguro Tokyo (JP)

(21) Appl. No.: 19/280,846

(22) Filed: Jul. 25, 2025

(30) Foreign Application Priority Data
Jan. 9, 2025 (JP) 2025-003662

(51) Int. Cl. H10D 12/00; H10D 62/10

(52) U.S. Cl. CPC H10D 12/415; H10D 12/481; H10D 62/107; H10D 62/126

(57) ABSTRACT

A semiconductor device according to one embodiment, includes a first electrode, a second electrode, a semiconductor layer, a third electrode, a first conductive part, and a first conductive layer. The second electrode is separated from the first electrode in a first direction. The semiconductor layer includes a first semiconductor region, a second semiconductor region, a third semiconductor region, and a plurality of guard ring regions. The first conductive part faces at least one of the plurality of guard ring regions via a second insulating part. The first conductive layer is positioned above the semiconductor layer. The first conductive layer is separated from at least a portion of the first conductive part in a direction perpendicular to the first direction. The first conductive layer is electrically connected to the first conductive part.

### CROSS-REFERENCE TO RELATED APPLICATIONS

This application is based upon and claims the benefit of priority from Japanese Patent Application No.2025-003662, filed on Jan. 9, 2025; the entire contents of which are incorporated herein by reference.

### FIELD

Embodiments relate to a semiconductor device.

### BACKGROUND

A semiconductor device includes, for example, a termination region outside a cell region; and the cell region includes elements such as IGBTs (Insulated Gate Bipolar Transistors), MOSFETs (Metal-Oxide-Semiconductor Field-Effect Transistors), diodes, etc.

### BRIEF DESCRIPTION OF THE DRAWINGS

FIG. 1 is a schematic plan view illustrating a semiconductor device according to an embodiment;

FIG. 2 is a schematic plan view illustrating a semiconductor device according to an embodiment;

FIG. 3 is a schematic cross-sectional view illustrating the semiconductor device according to the embodiment;

FIG. 4 is a schematic cross-sectional view illustrating the semiconductor device according to the embodiment;

FIG. 5 is a schematic cross-sectional view illustrating the semiconductor device according to the embodiment;

FIG. 6 is a schematic cross-sectional view illustrating another semiconductor device according to an embodiment;

FIG. 7 is a schematic cross-sectional view illustrating another semiconductor device according to an embodiment;

FIG. 8 is a schematic cross-sectional view illustrating another semiconductor device according to an embodiment;

FIG. 9 is a schematic cross-sectional view illustrating another semiconductor device according to an embodiment;

FIG. 10 is a schematic plan view illustrating another semiconductor device according to an embodiment;

FIG. 11 is a schematic cross-sectional view illustrating the semiconductor device according to an embodiment;

FIG. 12 is a schematic cross-sectional view illustrating the semiconductor device according to an embodiment;

FIG. 13 is a schematic plan view illustrating another semiconductor device according to an embodiment;

FIG. 14 is a schematic plan view illustrating another semiconductor device according to an embodiment;

FIG. 15 is a schematic plan view illustrating another semiconductor device according to an embodiment;

FIG. 16 is a schematic plan view illustrating another semiconductor device according to an embodiment; and

FIG. 17 is a schematic cross-sectional view illustrating another semiconductor device according to an embodiment.

### DETAILED DESCRIPTION

A semiconductor device according to one embodiment, includes a first electrode, a second electrode, a semiconductor layer, a third electrode, a first conductive part, and a first conductive layer. The second electrode is separated from the first electrode in a first direction. The semiconductor layer is located in a cell region of the device and in a termination region of the device. The termination region surrounds the cell region. The semiconductor layer is positioned between the first electrode and the second electrode in the cell region. The semiconductor layer includes a first surface a first surface proximate to the first electrode, and a second surface proximate to the second electrode. The semiconductor layer includes a first semiconductor region, a second semiconductor region, a third semiconductor region, a plurality of guard ring regions. The first semiconductor region is located in the cell region and the termination region. The first semiconductor region is of a first conductivity type. The second semiconductor region is located in the cell region between the first semiconductor region and the second electrode. The second semiconductor region is electrically connected to the second electrode. The second semiconductor region is of a second conductivity type. The third semiconductor region is located in the cell region between the second semiconductor region and the second electrode. The third semiconductor region is electrically connected to the second electrode. The third semiconductor region is of the first conductivity type. The plurality of guard ring regions is located in the termination region at the second surface side of the first semiconductor region. The plurality of guard ring regions surrounds the cell region. The plurality of guard ring regions is of the second conductivity type. The third electrode faces the second semiconductor region via a first insulating part. The first conductive part faces at least one of the plurality of guard ring regions via a second insulating part. The first conductive layer is positioned above the semiconductor layer. The first conductive layer is separated from at least a portion of the first conductive part in a direction perpendicular to the first direction. The first conductive layer is electrically connected to the first conductive part.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the embodiments described below, each embodiment may be implemented by inverting the p-type (an example of the second conductivity type) and the n-type (an example of the first conductivity type) of each semiconductor region.

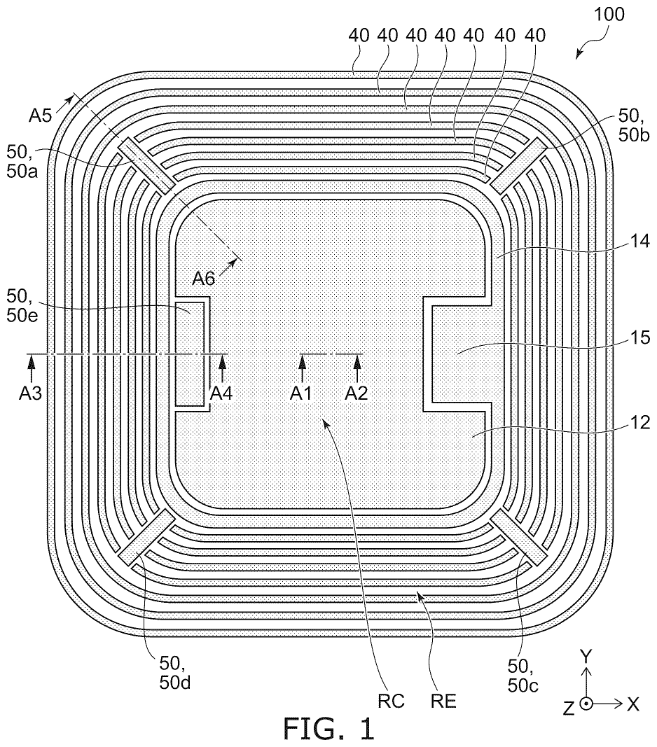

FIG. 1 is a schematic plan view illustrating a semiconductor device according to an embodiment.

As illustrated in FIG. 1, the semiconductor device 100 according to the embodiment includes a cell region RC, and a termination region RE surrounding the cell region RC. In the example, an IGBT is located in the cell region RC. Elements such as a MOSFET, a diode, etc., may be located in the cell region RC.

The semiconductor device 100 includes a first electrode 11 (e.g., a collector electrode) that will be described below, a second electrode 12 (e.g., an emitter electrode) illustrated in FIG. 1, an electrode pad 15 (e.g., a gate electrode pad), and a wiring part 14 (e.g., a gate wiring part). The second electrode 12 is located in the cell region RC at the upper surface side of the semiconductor device 100. The planar shape of the second electrode 12 is, for example, rectangular. “Rectangular” includes not only shapes having exactly rectangular outer edges, but also shapes that are substantially rectangular. In other words, “rectangular” also includes, for example, rectangles with rounded corners, rectangles with notched portions, etc.

The electrode pad 15 and the wiring part 14 are arranged with the second electrode 12 in directions in the X-Y plane. The electrode pad 15 and the wiring part 14 are separated from the second electrode 12 and insulated from the second electrode 12. The wiring part 14 surrounds the second electrode 12, is continuous with the electrode pad 15, and is electrically connected to the electrode pad 15.

The semiconductor device 100 also includes multiple electrodes 40 located in the termination region RE. The electrodes 40 are arranged with the second electrode 12 in directions in the X-Y plane. The electrodes 40 have ring shapes surrounding the second electrode 12, the electrode pad 15, and the wiring part 14. The multiple electrodes 40 are separated from each other. The electrodes 40 are separated from the second electrode 12, the electrode pad 15, and the wiring part 14, and are insulated from the second electrode 12, the electrode pad 15, and the wiring part 14. For example, the potentials of the electrodes 40 are floating.

The semiconductor device 100 includes a conductive layer 50. In the example, multiple conductive layers 50 are included. Specifically, five conductive layers 50, i.e., conductive layers 50a to 50e, are included. For example, the conductive layers 50 are arranged with the second electrode 12 in directions in the X-Y plane. The conductive layers 50 are separated from the second electrode 12, the electrode pad 15, the wiring part 14, and the electrodes 40 and are insulated from the second electrode 12, the electrode pad 15, the wiring part 14, and the electrodes 40. Although the potentials of the conductive layers 50 are, for example, floating, voltages can be applied as necessary. The conductive layers 50a to 50d are located in the termination region RE. The conductive layer 50e is arranged along the outer edge of the second electrode 12. The conductive layer 50e is positioned at the side opposite to the electrode pad 15 when viewed from the second electrode 12.

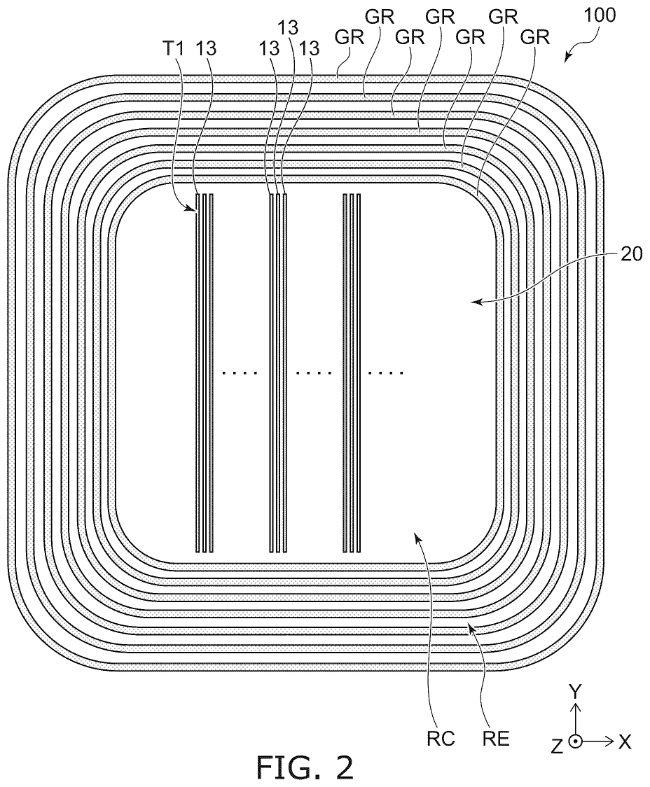

FIG. 2 is a schematic plan view illustrating a semiconductor device according to an embodiment.

FIG. 2 illustrates the layout of layers under the electrodes (the second electrode 12, the electrode pad 15, the electrode 40, the conductive layer 50, etc.), the wiring parts, the insulating films, etc., located at the upper surface side of the semiconductor device 100, which are not illustrated. A guard ring region GR0 and a conductive part 60 that are described below also are not illustrated for simplicity.

The semiconductor device 100 includes a semiconductor layer 20 and multiple third electrodes 13 (e.g., gate electrodes). The semiconductor layer 20 is located in the cell region RC and the termination region RE. In the example as described below, the third electrodes 13 are located inside trenches T1 formed in the semiconductor layer 20. In the cell region RC, the multiple third electrodes 13 are arranged in the X-direction; and each third electrode 13 extends in the Y-direction.

The semiconductor layer 20 includes multiple guard ring regions GR. The guard ring regions GR are located in the termination region RE at the surface of the semiconductor layer 20. The guard ring regions GR have ring shapes surrounding the cell region RC. The multiple guard ring regions GR are separated from each other.

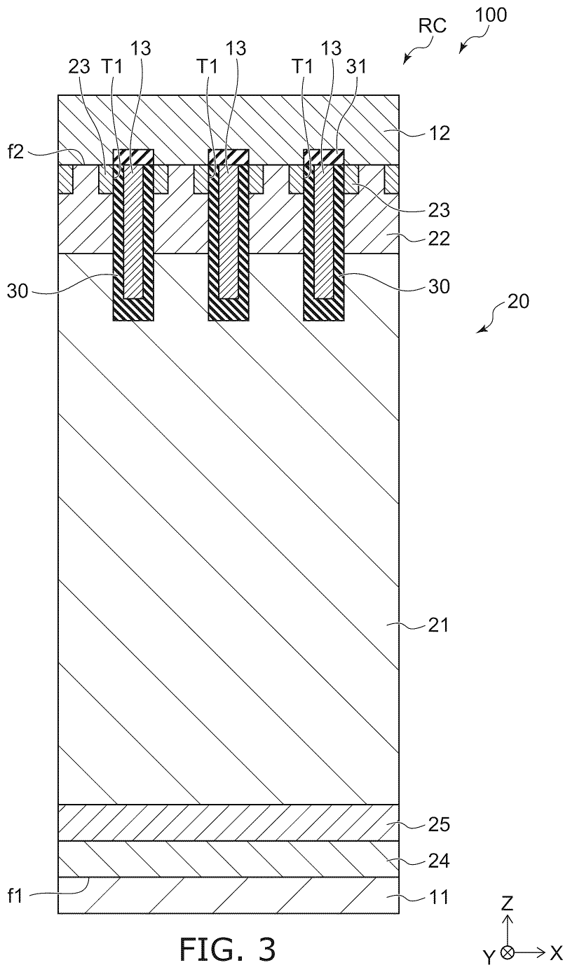

FIG. 3 is a schematic cross-sectional view illustrating the semiconductor device according to the embodiment.

FIG. 3 illustrates a cross section along line A1-A2 shown in FIG. 1, i.e., a cross section of the cell region RC.

As illustrated in FIG. 3, the second electrode 12 is separated from the first electrode 11 in a Z-direction. In the description of the embodiments, the direction from the first electrode 11 toward the second electrode 12 is referred to as the Z-direction (a first direction). For example, the Z-direction is the thickness direction of the semiconductor layer 20. In the description, the direction from the first electrode 11 toward the second electrode 12 is referred to as “up” or “above”, and the opposite direction is referred to as “down” or “below”. These directions are based on the relative positional relationship between the first electrode 11 and the second electrode 12, and are independent of the direction of gravity. The X-direction, the Y-direction, and the Z-direction are perpendicular to each other.

The semiconductor layer 20 is positioned between the first electrode 11 and the second electrode 12 in the cell region RC. The semiconductor layer 20 includes a first surface f1 (the lower surface) at the first electrode 11 side, and a second surface f2 (the upper surface) at the second electrode 12 side. The first surface f1 and the second surface f2 extend along the X-Y plane. The first electrode 11 contacts the first surface f1 and is electrically connected to the semiconductor layer 20. The second electrode 12 contacts the second surface f2 and is electrically connected to the semiconductor layer 20.

The semiconductor layer 20 includes a first semiconductor region 21 (e.g., a drift region), a second semiconductor region 22 (e.g., a base region), and a third semiconductor region 23 (e.g., a source region). The semiconductor layer 20 may further include a fourth semiconductor region 24 (e.g., a collector region) and a fifth semiconductor region 25 (e.g., a buffer region).

The fourth semiconductor region 24 is located on the first electrode 11. The fourth semiconductor region 24 contacts the first electrode 11. The fourth semiconductor region 24 is of a second conductivity type.

The fifth semiconductor region 25 is located on the fourth semiconductor region 24. The fifth semiconductor region 25 is of a first conductivity type.

The first semiconductor region 21 is located on the fifth semiconductor region 25. The first semiconductor region 21 is of the first conductivity type. The first-conductivity-type impurity concentration in the first semiconductor region 21 is less than the first-conductivity-type impurity concentration in the fifth semiconductor region 25.

The second semiconductor region 22 is located on the first semiconductor region 21 in the cell region RC. In other words, the second semiconductor region 22 is between the first semiconductor region 21 and the second electrode 12. The second semiconductor region 22 is of the second conductivity type.

The third semiconductor region 23 is located on a portion of the second semiconductor region 22 in the cell region RC. In other words, the third semiconductor region 23 is between the second semiconductor region 22 and the second electrode 12. The third semiconductor region 23 is of the first conductivity type.

The third electrode 13 faces the first semiconductor region 21, the second semiconductor region 22, and the third semiconductor region 23 via an insulating part 30 (a first insulating part). In the example, the third electrode 13 and the insulating part 30 are located inside the trench T1 formed in the semiconductor layer 20. The trench T1 extends from the second surface f2 to the first semiconductor region 21 in the Z-direction. The insulating part 30 is located at the inner wall of the trench T1. The insulating part 30 contacts the first semiconductor region 21, the second semiconductor region 22, and the third semiconductor region 23. The third electrode 13 is located at the inner side of the insulating part 30 inside the trench T1, and is insulated from the semiconductor layer 20 by the insulating part 30. The third electrode 13 is arranged with the first semiconductor region 21, the second semiconductor region 22, and the third semiconductor region 23 in the X-direction.

The second electrode 12 contacts the second and third semiconductor regions 22 and 23 and is electrically connected to the second and third semiconductor regions 22 and 23. The second-conductivity-type impurity concentration of a contact part of the second semiconductor region 22 that contacts the second electrode 12 may be greater than those of the other parts of the second semiconductor region 22. The second electrode 12 is insulated from the third electrode 13 by an insulating layer 31.

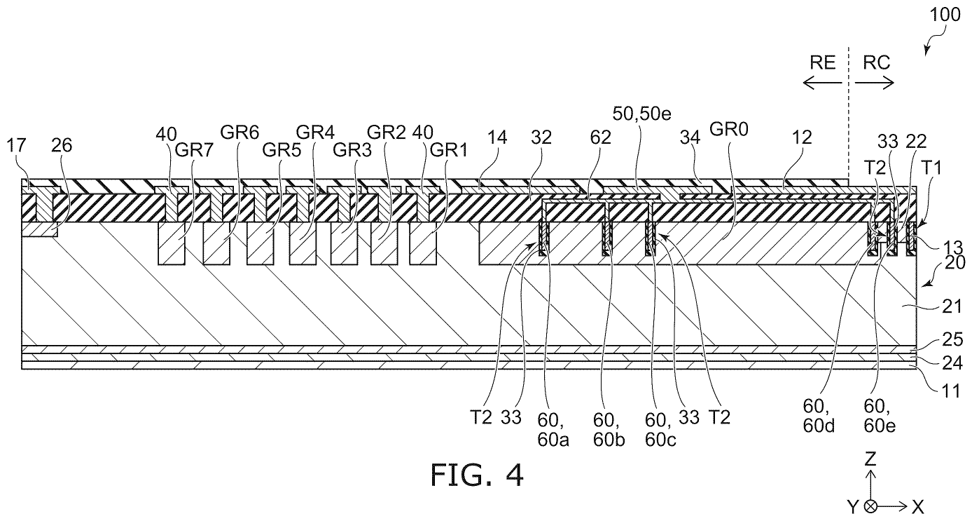

FIG. 4 is a schematic cross-sectional view illustrating the semiconductor device according to the embodiment.

FIG. 4 illustrates a cross section along line A3-A4 shown in FIG. 1, i.e., a cross section of the termination region RE and a portion of the cell region RC.

The first electrode 11, the fourth semiconductor region 24, the fifth semiconductor region 25, and the first semiconductor region 21 extend through the cell region RC and the termination region RE.

In the example, the multiple guard ring regions GR include guard ring regions GR0 to GR7. The guard ring regions GR are located on the first semiconductor region 21 at the second surface f2 side of the semiconductor layer 20. For example, the guard ring regions GR extend lower than the trenches T1 from the second surface f2. The guard ring regions GR are semiconductor regions of the second conductivity type. Portions of the first semiconductor region 21 are positioned between mutually-adjacent guard ring regions GR.

The guard ring region GR0, the guard ring region GR1, the guard ring region GR2, the guard ring region GR3, the guard ring region GR4, the guard ring region GR5, the guard ring region GR6, and the guard ring region GR7 are arranged in this order from the cell region RC side. For example, the potentials of the guard ring regions GR are in floating states. For example, the guard ring regions GR cause a depletion layer to spread in the termination region RE and suppress the electric field.

For example, the guard ring region GR0 (an innermost guard ring region positioned furthest toward the cell region RC among the guard ring regions GR) may contact the second semiconductor region 22. The guard ring region GR0 “being located in the termination region RE and surrounding the cell region RC” may include the case where a portion of the guard ring region GR0 extends beyond the boundary between the cell region RC and the termination region RE and extends to the end part of the cell region RC.

The guard ring region GR0 extends below the second electrode 12 and the wiring part 14. The wiring part 14 is insulated from the semiconductor layer 20 by an insulating layer 32.

The electrodes 40 are located respectively on the guard ring regions GR1 to GR7 in contact with the guard ring regions GR1 to GR7, and are electrically connected respectively to the guard ring regions GR1 to GR7.

The semiconductor layer 20 includes a semiconductor region 26 of the first conductivity type positioned at the outer end part of the termination region RE. The semiconductor region 26 is located on the first semiconductor region 21 and surrounds the cell region RC. The semiconductor region 26 is, for example, an EQPR (Equi-potential Ring). The first-conductivity-type impurity concentration in the semiconductor region 26 is greater than the first-conductivity-type impurity concentration in the first semiconductor region 21. An electrode 17 is located on the semiconductor region 26 in contact with the semiconductor region 26, and is electrically connected to the semiconductor region 26.

The electrode 40 and the electrode 17 are separated from the first semiconductor region 21 by the insulating layer 32 on the semiconductor layer 20.

The conductive layer 50 is positioned above the semiconductor layer 20 with the insulating layer 32 interposed. For example, the conductive layer 50 is positioned above a portion of the guard ring region GR. In the example of FIG. 4, the conductive layer 50e is positioned above a portion of the guard ring region GR0.

The semiconductor device 100 further includes the conductive part 60 (e.g., an endothermic electrode). The conductive part 60 faces the guard ring region GR or the second semiconductor region 22 via an insulating part 33. In the example, multiple conductive parts 60 are included. Specifically, three conductive parts 60, i.e., conductive parts 60a to 60c are located in the termination region RE. Two conductive parts 60, i.e., conductive parts 60d and 60e, are located in the cell region RC.

The conductive part 60 and the insulating part 33 are located inside a trench T2 formed in the semiconductor layer 20. The insulating part 33 is located at the inner wall of the trench T2. The conductive part 60 is located at the inner side of the insulating part 33 inside the trench T2, and is insulated from the semiconductor layer 20 by the insulating part 33. In the example, multiple conductive parts 60 are arranged in the X-direction; and each conductive part 60 extends in the Y-direction.

In the termination region RE, the trench T2 extends in the Z-direction from the second surface f2, and is located inside the guard ring region GR. In the termination region RE, the insulating part 33 contacts the guard ring region GR. In the example, the conductive parts 60a to 60c are located inside the trenches T2 formed in the guard ring region GR0. In other words, the conductive parts 60a to 60c are located inside the guard ring region GR0 and face the guard ring region GR0 via the insulating part 33.

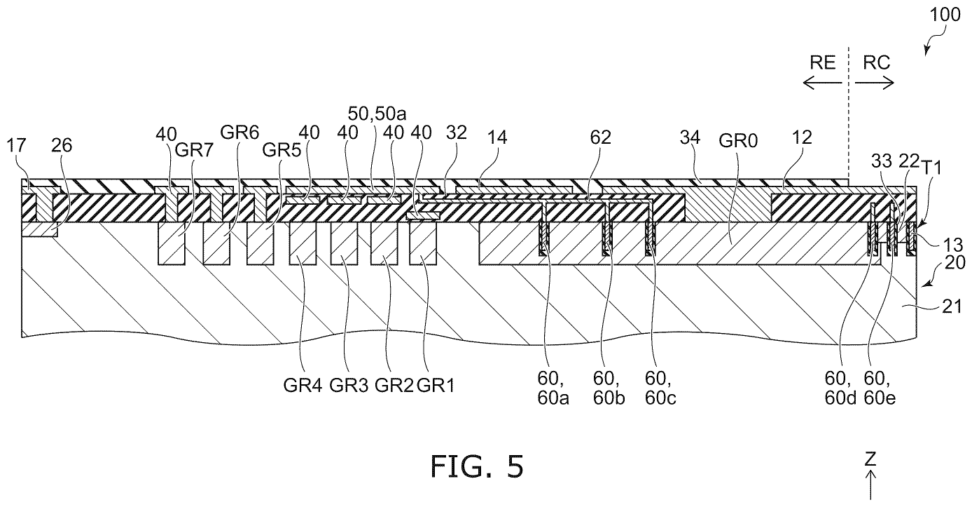

The conductive part 60a is below the wiring part 14. Portions of the conductive parts 60b and 60c are below the conductive layer 50e. As in FIG. 5 below, other portions of the conductive parts 60b and 60c are below the second electrode 12.

In the cell region RC, the trench T2 extends from the second surface f2 to the first semiconductor region 21 in the Z-direction. In the cell region RC, the insulating part 33 contacts the first and second semiconductor regions 21 and 22. The conductive parts 60d and 60e face the first semiconductor region 21 and the second semiconductor region 22 via the insulating part 33. The conductive parts 60d and 60e are arranged with the third electrode 13 in the X-direction below the second electrode 12.

Each of the multiple conductive layers 50 is electrically connected to one or multiple conductive parts 60. Each of the multiple conductive parts 60 is electrically connected to one or multiple conductive layers 50.

Specifically, the conductive part 60 and the conductive layer 50 on the insulating layer 32 are connected by a wiring part 62. The wiring part 62 is located inside the insulating layer 32, which is located on the semiconductor layer 20. In other words, a portion of the wiring part 62 contacts the top of the lower part of the insulating layer 32; and the upper part of the insulating layer 32 contacts the top of the portion of the wiring part 62. The insulating layer 32 may have a multilayer structure in which multiple insulating layers are stacked. A portion of the wiring part 62 extends in the X-Y plane. The wiring part 62 includes a part that does not overlap the conductive layer 50 in the Z-direction, and a part that does not overlap the conductive part 60 in the Z-direction.

As illustrated in FIG. 4, the wiring part 62 connects the conductive layer 50e and the conductive parts 60a to 60e.

An insulating layer 34 (a protective film) is located on the second electrode 12, the conductive layer 50, the wiring part 14, the electrode 40, the electrode 17, and the insulating layer 32 in the termination region RE. In the termination region RE, the insulating layer 34 may cover the entire upper surface of the conductive layer 50. The conductive part 60 and the conductive layer 50 are insulated from the second electrode 12, the third electrode 13, the electrode 40, and the semiconductor layer 20.

FIG. 5 is a schematic cross-sectional view illustrating the semiconductor device according to the embodiment.

FIG. 5 illustrates a cross section along line A5-A6 shown in FIG. 1.

The second electrode 12 contacts the top of the guard ring region GR0, and is electrically connected to the guard ring region GR0.

As illustrated in FIG. 5, the wiring part 62 connects the conductive layer 50a and the conductive parts 60a to 60c. The wiring part 62 may connect the conductive layer 50a and the conductive parts 60d and 60e.

The conductive layer 50 and the conductive part 60 that are connected by the wiring part 62 may be separated from each other. For example, the conductive layer 50a does not overlap the conductive parts 60a to 60e in the Z-direction. For example, the conductive layer 50e does not overlap at least portions of the conductive parts 60a to 60e in the Z-direction. Thus, the conductive layer 50 does not overlap, in the Z-direction, at least a portion of the conductive parts 60 connected to the conductive layer 50 by the wiring part 62. In other words, the conductive layer 50 is separated, in a direction perpendicular to the Z-direction, from at least a portion of the conductive part 60 electrically connected to the conductive layer 50.

Although not illustrated, the conductive layers 50b, 50c, and 50d illustrated in FIG. 1 are similarly connected by wiring parts to the conductive parts 60 located inside the trenches T2 of the semiconductor layer 20.

A portion of the electrode 40 extends through the insulating layer 32 below the conductive layer 50a. Thus, in the range in which the conductive layer 50 and the guard ring region GR overlap in the Z-direction, a portion of the electrode 40 connected with the guard ring region GR is positioned between the guard ring region GR and the conductive layer 50.

Examples of the materials of the components of the semiconductor device 100 will now be described.

The first semiconductor region 21, the second semiconductor region 22, the third semiconductor region 23, the fourth semiconductor region 24, the fifth semiconductor region 25, the semiconductor region 26, and the guard ring region GR include silicon, silicon carbide, gallium nitride, or gallium arsenide as a semiconductor material. For example, the semiconductor layer 20 is a semiconductor substrate such as a silicon substrate, etc.

When silicon is used as the semiconductor material, arsenic, phosphorus, or antimony can be used as an n-type impurity. Boron can be used as a p-type impurity.

The third electrode 13 includes a conductive material such as polysilicon, etc. An impurity may be added to the conductive material.

The conductive part 60 includes a material having a larger thermal conductivity than the material of the third electrode 13 such as, for example, a metal, etc. The conductive part 60 includes, for example, at least one selected from the group consisting of aluminum, copper, tungsten, titanium, gold, germanium, platinum, and nickel.

The insulating part 30, the insulating layer 31, the insulating layer 32, the insulating part 33, and the insulating layer 34 include insulating materials such as silicon oxide, silicon nitride, etc.

The first electrode 11, the second electrode 12, the wiring part 14, the electrode pad 15, the electrode 40, the electrode 17, the conductive layer 50, and the wiring part 62 include, for example, metals such as at least one selected from the group consisting of aluminum, copper, tungsten, titanium, gold, germanium, platinum, and nickel.

Operations of the semiconductor device 100 will now be described.

A voltage that is not less than a threshold is applied to the third electrode 13 in a state in which a voltage that is positive with respect to the second electrode 12 is applied to the first electrode 11. As a result, an inversion layer is formed in the second semiconductor region 22; and the state is switched to an on-state. For example, electrons flow from the second electrode 12 toward the first semiconductor region 21 via the third semiconductor region 23 and a channel. For example, holes flow from the first electrode 11 toward the first semiconductor region 21 via the fourth semiconductor region 24. Subsequently, when the voltage that is applied to the third electrode 13 drops below the threshold, the inversion layer in the second semiconductor region 22 disappears, and the state is switched to an off-state.

The embodiment as described above includes the first conductive part (e.g., the conductive part 60a) and the first conductive layer (e.g., the conductive layer 50a) that is electrically connected to the first conductive part. The first conductive layer is separated from at least a portion of the first conductive part in a direction perpendicular to the Z-direction. The heat that is generated in the semiconductor layer 20 can be directed from the first conductive part to the first conductive layer at a distant position; and the controllability of the temperature can be improved.

In other words, for example, the temperature rise of the semiconductor layer 20 at the periphery of the first conductive part can be suppressed. The temperature of the semiconductor layer 20 below the first conductive layer can be increased by the increase of the temperature of the first conductive layer due to the heat from the first conductive part. Thus, the temperature distribution inside the semiconductor device 100 can be controlled. For example, the increase of the temperature below the first conductive layer makes it difficult for impact ionization to occur. As a result, for example, breakdown can be suppressed, and the reliability can be increased.

The first conductive part and the first conductive layer are connected by the wiring part 62. By including the wiring part 62, heat can be directed to a more distant position. For example, the reliability can be further increased by guiding the heat to a location at which the electric field is intense. The first conductive layer (e.g., the conductive layer 50a) may not overlap the first conductive part (e.g., the conductive part 60a) in the Z-direction.

For example, the thermal conductivity of the first conductive part is greater than the thermal conductivity of the third electrode 13. By setting the thermal conductivity of the first conductive part to be high, the heat can be directed to the first conductive layer more efficiently. The thermal conductivity of the first conductive part may be greater than or equal to the thermal conductivity of the second electrode 12. However, the thermal conductivity of the first conductive part may be less than the thermal conductivity of the second electrode 12.

There are cases where breakdown due to impact ionization, etc., occurs easily in the termination region RE. In contrast, the conductive layer 50 is positioned above a portion of the guard ring region GR. For example, the conductive layers 50a to 50d are positioned above a portion of the guard ring regions GR1 to GR4. By positioning the first conductive layer above the guard ring region GR, for example, the temperature of the termination region RE can be increased, impact ionization can be suppressed, and the reliability can be increased.

The multiple guard ring regions GR include the inner guard ring region (e.g., the guard ring regions GR1 to GR4) and the outer guard ring region (e.g., the guard ring regions GR5 to GR7) surrounding the inner guard ring region. There are cases where the electric field in the termination region RE is more intense proximate to the cell region RC. For example, there are cases where, compared to the periphery of the outer guard ring region, the electric field is more intense and impact ionization occurs easily at the periphery of the inner guard ring region. In contrast, the conductive layers 50a to 50d are positioned above the inner guard ring region. By positioning the first conductive layer above the inner guard ring region, for example, the temperature of the periphery of the inner guard ring region can be increased, and the reliability can be further increased. In the example, the conductive layer 50 is not located above the outer guard ring region. However, the conductive layer 50 may be located above the outer guard ring region as well.

For example, there are cases where the electric field is intense at the periphery of the guard ring region GR0 (the innermost guard ring region) adjacent to the cell region RC. In contrast, the conductive layer 50e is arranged along the outer edge of the second electrode 12 above the guard ring region GR0. As a result, for example, the temperature of the periphery of the guard ring region GR0 can be increased, and the reliability can be further increased.

For example, as illustrated in FIG. 2, the guard ring region GR has a rectangular shape with four rounded corners. In other words, the guard ring region GR has a shape with curved corner parts that surrounds the cell region RC. There are cases where the electric field is intense at the curved parts. In contrast, as illustrated in FIG. 1, the conductive layers 50a to 50d are located respectively above the four corner parts of the rectangular semiconductor layer 20. The conductive layers 50a to 50d are positioned respectively above the corner parts of the guard ring regions GR. By positioning the first conductive layer above the corner part of the guard ring region GR, for example, the temperature of the corner part periphery of the guard ring region GR can be increased, and the reliability can be further increased. For example, the conductive layers 50a to 50d extend over diagonals of the rectangular semiconductor layer 20.

For example, as illustrated in FIG. 4, the second conductive part (e.g., the conductive part 60e) facing the second semiconductor region 22 via the insulating part 33 and the second conductive layer (e.g., the conductive layer 50e) electrically connected to the second conductive part are included. As described with reference to FIGS. 4 and 5, the second conductive part (e.g., the conductive part 60e) may be electrically connected to the first conductive layer (e.g., the conductive layer 50a). At least a portion of the second conductive part is separated from the first and second conductive layers in a direction perpendicular to the Z-direction. The second conductive part may not overlap the first and second conductive layers in the Z-direction. The heat that is generated in the semiconductor layer 20 can be directed to the first and second conductive layers that are distant to the second conductive part; and the controllability of the temperature can be improved.

The first conductive part (e.g., the conductive part 60a) may be electrically connected to the second conductive layer (e.g., the conductive layer 50e). At least a portion of the first conductive part is separated from the second conductive layer in a direction perpendicular to the Z-direction.

The thermal conductivity of the wiring part 62 may be the same as the thermal conductivity of the conductive layer 50. The thermal conductivity of the wiring part 62 and the thermal conductivity of the conductive layer 50 each may be the same as the thermal conductivity of the second electrode 12 or the electrode 40.

The thermal conductivity of the wiring part 62 may be greater than the thermal conductivity of the conductive layer 50. When the thermal conductivity of the wiring part 62 is high, for example, the heat can be efficiently directed to the conductive layer 50. The thermal conductivity of the wiring part 62 may be greater than the thermal conductivity of the second electrode 12 or the electrode 40. The thermal conductivity of the second electrode 12 or the electrode 40 may be greater than the thermal conductivity of the conductive layer 50.

The thermal conductivity of the wiring part 62 may be less than the thermal conductivity of the conductive layer 50. When the thermal conductivity of the wiring part 62 is low, for example, the temperature of the semiconductor layer 20 can be increased below the wiring part 62 as well. The thermal conductivity of the wiring part 62 may be less than the thermal conductivity of the second electrode 12 or the electrode 40. The thermal conductivity of the second electrode 12 or the electrode 40 may be less than the thermal conductivity of the conductive layer 50.

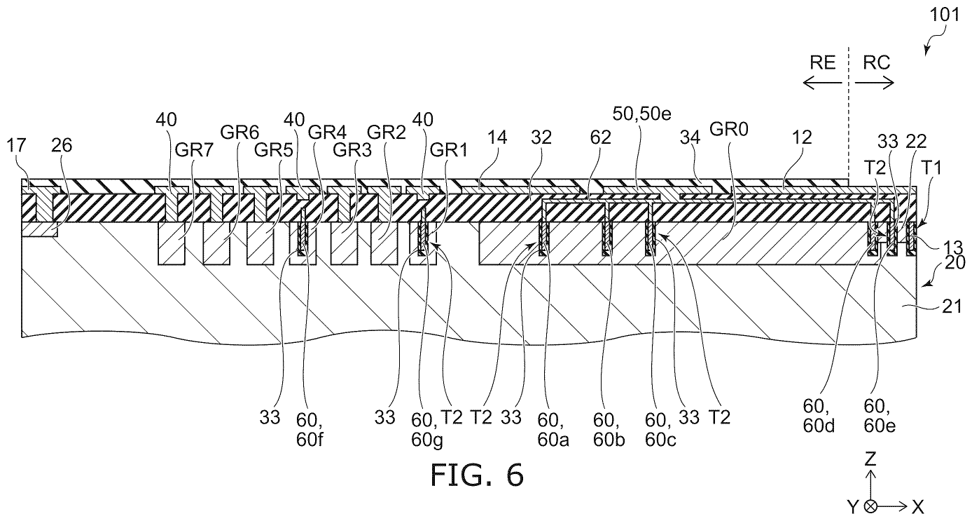

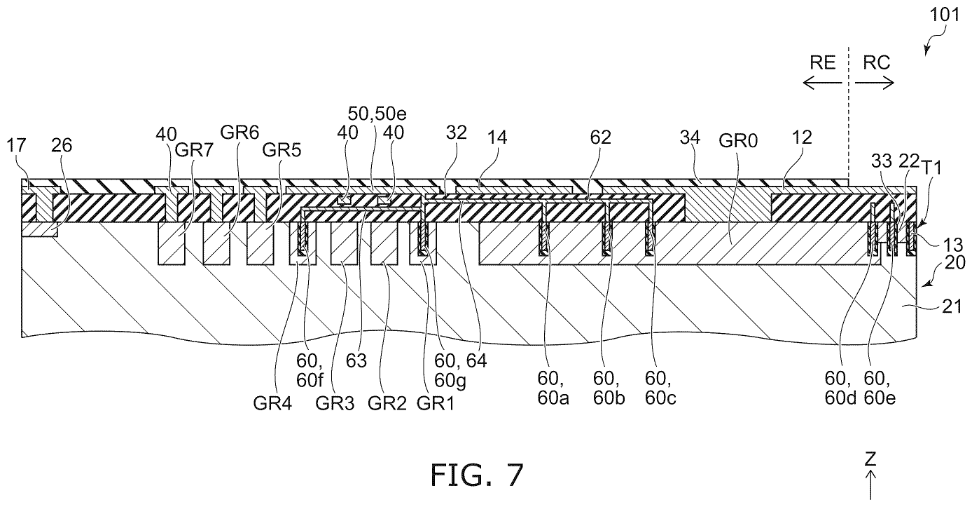

FIGS. 6 and 7 are schematic cross-sectional views illustrating another semiconductor device according to an embodiment.

Although not illustrated, a configuration similar to the example of FIGS. 1 to 3 above is included in the semiconductor device 101 illustrated in FIGS. 6 and 7. FIG. 6 illustrates a cross section at a position similar to line A3-A4 of FIG. 1. FIG. 7 illustrates a cross section at a position similar to line A5-A6 of FIG. 1.

The multiple conductive parts 60 further include a conductive part 60f and a conductive part 60g. As illustrated in FIG. 6, the conductive part 60f is located inside the trench T2 located in the guard ring region GR4. The conductive part 60f is located inside the guard ring region GR4 and faces the guard ring region GR4 via the insulating part 33. A portion of the conductive part 60f extends in the Y-direction. The conductive part 60f may extend inside the guard ring region GR4 to surround the cell region RC similarly to the guard ring region GR4.

The conductive part 60g is located inside the trench T2 located in the guard ring region GR1. The conductive part 60g is located inside the guard ring region GR1 and faces the guard ring region GR1 via the insulating part 33. A portion of the conductive part 60g extends in the Y-direction. The conductive part 60g may extend inside the guard ring region GR1 to surround the cell region RC similarly to the guard ring region GR1.

As illustrated in FIG. 7, the wiring part 62 connects the conductive layer 50a and the conductive part 60f and connects the conductive layer 50a and the conductive part 60g. The wiring part 62 may connect the conductive layer 50e (see FIG. 6) and the conductive part 60f and connect the conductive layer 50e and the conductive part 60g. The wiring part 62 may connect the conductive layer 50d (see FIG. 1) and the conductive part 60f and connect the conductive layer 50d and the conductive part 60g.

The conductive layers 50 (the conductive layers 50a to 50e) do not overlap at least portions of the conductive parts 60f and 60g in the Z-direction.

In the example as well, the first conductive part (e.g., the conductive part 60a) and the first conductive layer (e.g., the conductive layer 50a) that are electrically connected to each other are included. The third conductive part (e.g., the conductive part 60f) also can be included. The third conductive part is electrically connected to at least one of the first conductive layer or the third conductive layer (e.g., the conductive layer 50d). Thus, by including multiple conductive parts 60 and multiple conductive layers 50, the controllability of the temperature distribution can be further improved.

In the example above, the conductive parts 60a, 60e, and 60f are illustrated as the first, second, and third conductive parts; and the conductive layers 50a, 50e, and 50d are illustrated as the first, second, and third conductive layers; however, the embodiments are not limited thereto. The first and third conductive parts may be any of the conductive parts 60 located in the guard ring regions GR. The second conductive part may be any of the conductive parts 60 located in the cell region RC. The first to third conductive layers may be any of the conductive layers 50.

The wiring part 62 may include multiple wiring layers. For example, as illustrated in FIG. 7, a wiring layer 63 and a wiring layer 64 are included. The wiring layer 63 and the wiring layer 64 are at mutually-different Z-direction positions. In other words, the wiring part 62 may be multilayer wiring. By including multiple wiring layers, for example, the conductive part 60 and the conductive layer 50 that are separated from each other can be easily connected, and the controllability of the temperature distribution can be further improved.

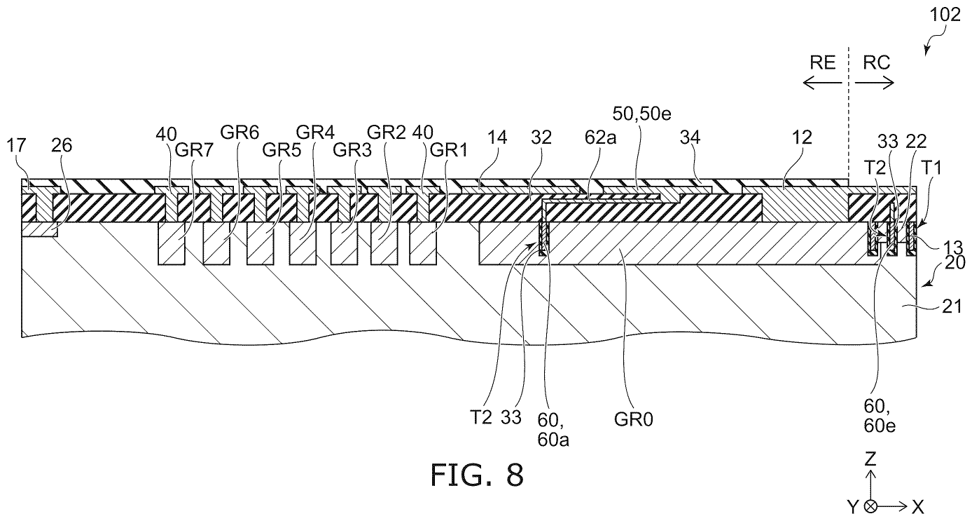

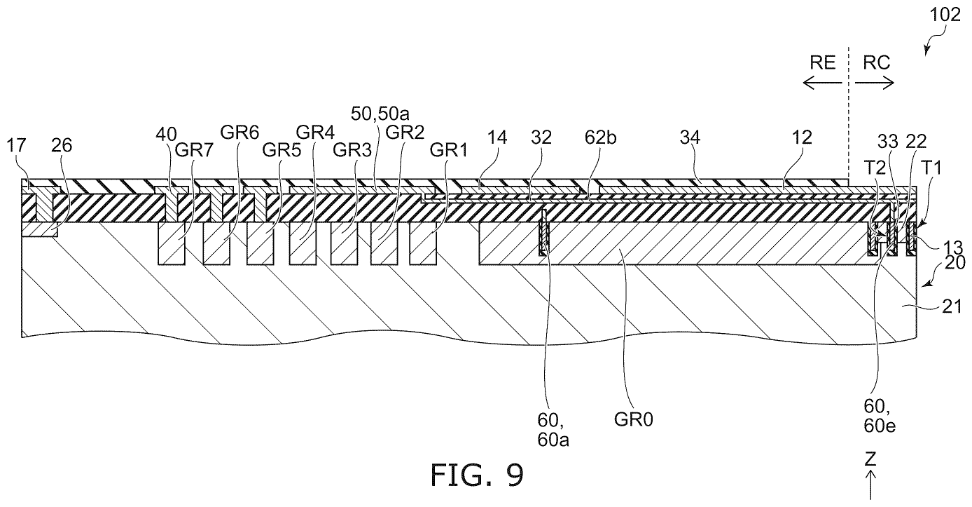

FIGS. 8 and 9 are schematic cross-sectional views illustrating another semiconductor device according to an embodiment.

Although not illustrated, a configuration similar to the example of FIGS. 1 to 3 above is included in the semiconductor device 102 illustrated in FIGS. 8 and 9. FIG. 8 illustrates a cross section at a position similar to line A3-A4 of FIG. 1. FIG. 9 illustrates a cross section at a position similar to line A5-A6 of FIG. 1.

As illustrated in FIG. 8, the conductive layer 50e is connected to the conductive part 60a via a wiring part 62a. The conductive layer 50e may not be electrically connected to the conductive part 60e, and may be insulated from the conductive part 60e.

As illustrated in FIG. 9, the conductive layer 50a is connected to the conductive part 60e via a wiring part 62b. The conductive layer 50a may not be electrically connected to the conductive part 60a, and may be insulated from the conductive part 60a.

Thus, the multiple conductive layers 50 may be electrically isolated from each other. The multiple conductive parts 60 may be electrically isolated from each other.

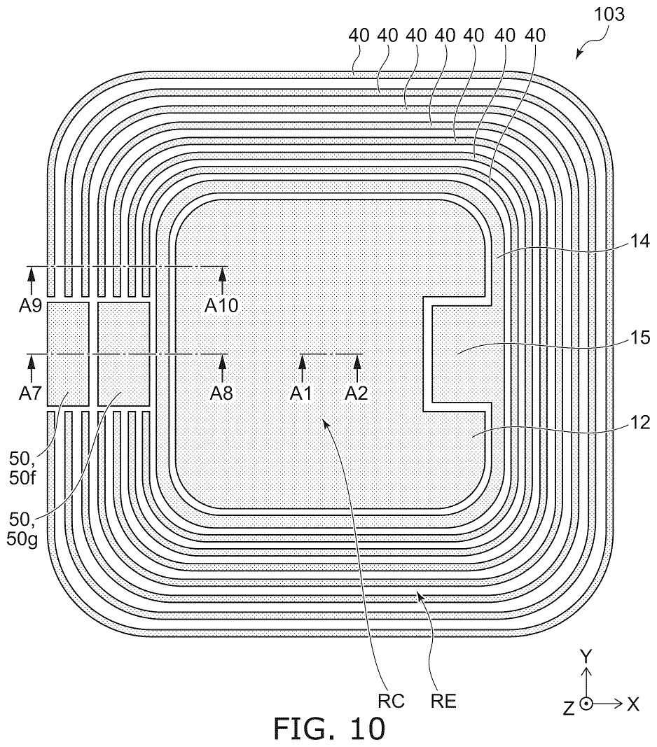

FIG. 10 is a schematic plan view illustrating another semiconductor device according to an embodiment.

In the semiconductor device 103 illustrated in FIG. 10, conductive layers 50f and 50g are provided as the conductive layer 50. The conductive layer 50f is arranged with the conductive layer 50g in the X-direction. The conductive layer 50f and the conductive layer 50g are positioned above the part of the guard ring region GR extending linearly along the Y-direction. In the semiconductor device 103, the first electrode 11, the second semiconductor region 22, the third semiconductor region 23, the fourth semiconductor region 24, the fifth semiconductor region 25, and the like are provided, similarly to the previously described semiconductor devices. The semiconductor device 103 may have a configuration similar to the configuration illustrated in FIGS. 2 and 3.

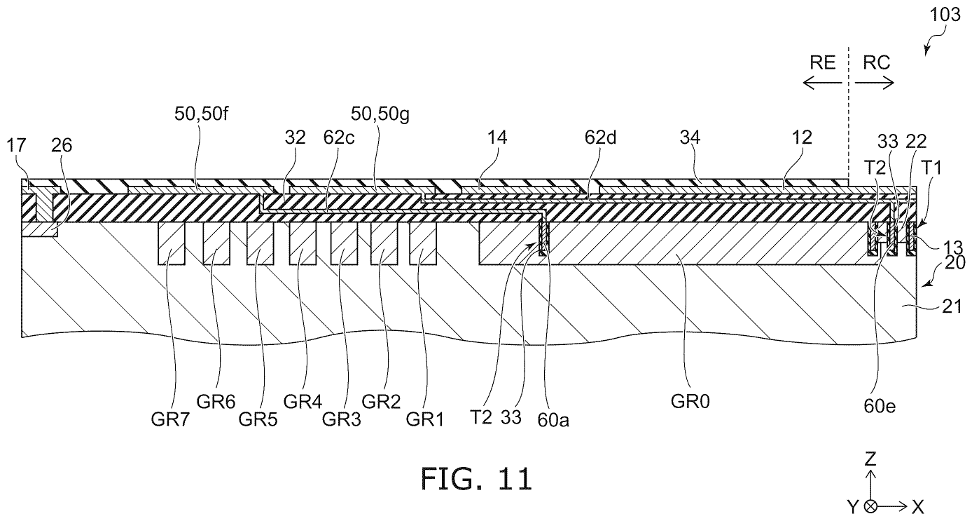

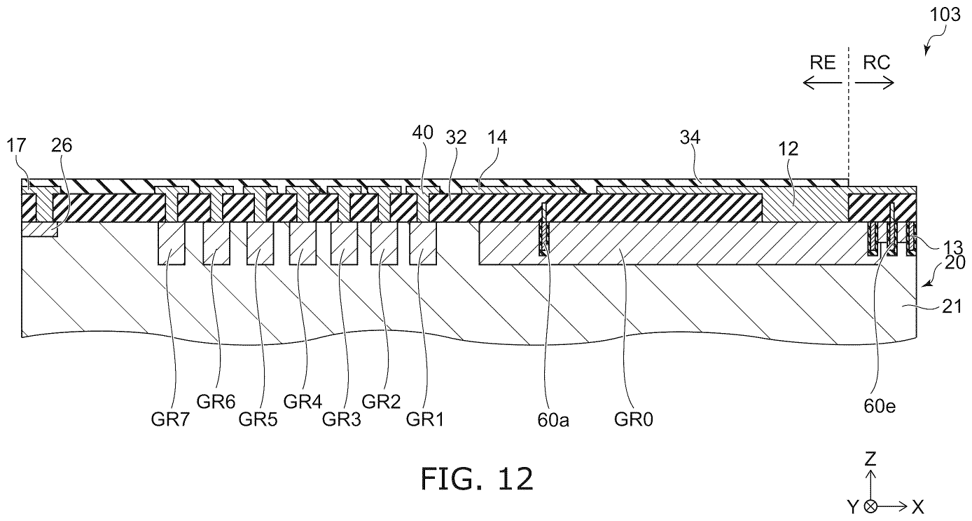

FIGS. 11 and 12 are schematic cross-sectional views illustrating the semiconductor device according to the embodiment.

FIG. 11 illustrates a cross section along line A7-A8 shown in FIG. 10. FIG. 12 illustrates a cross section along line A9-A10 shown in FIG. 10. As illustrated in FIG. 11, the conductive layer 50f is positioned above the guard ring regions GR5 to GR7. The conductive layer 50g is positioned above the guard ring regions GR1 to GR4.

The conductive part 60a is connected to the conductive layer 50f via a wiring part 62c. The conductive part 60a may not be electrically connected to the conductive layer 50g, and may be insulated from the conductive layer 50g.

The conductive part 60e is connected to the conductive layer 50g via a wiring part 62d. The conductive part 60e may not be electrically connected to the conductive layer 50f, and may be insulated from the conductive layer 50f.

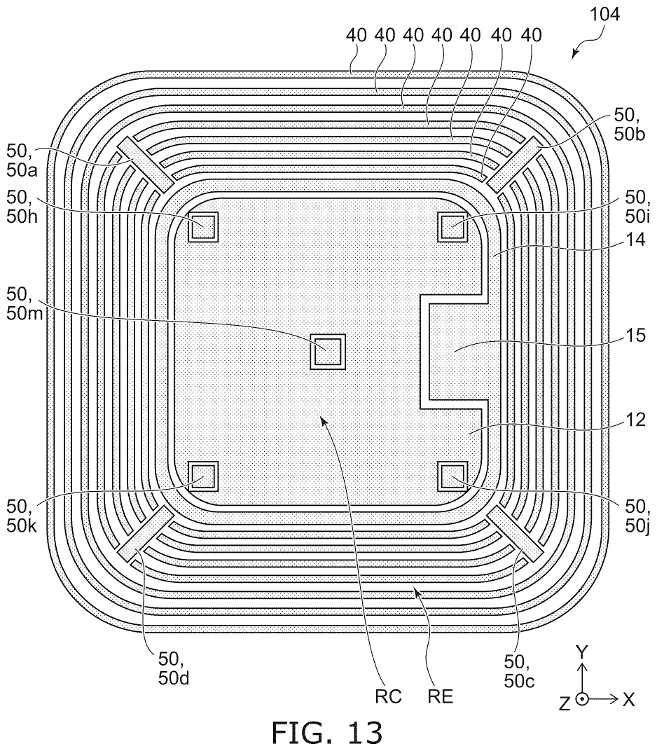

FIGS. 13 to 16 are schematic plan views illustrating other semiconductor devices according to embodiments.

Although not illustrated, the multiple guard ring regions GR (e.g., the guard ring regions GR0 to GR7), the semiconductor layer 20 (the first semiconductor region 21, the second semiconductor region 22, the third semiconductor region 23, the fourth semiconductor region 24, the fifth semiconductor region 25), the multiple third electrodes 13, the multiple conductive parts 60, the wiring part 62, the first electrode 11, etc., are included in the semiconductor devices illustrated in FIGS. 13 to 16, similarly to the previously described semiconductor devices. The semiconductor devices illustrated in FIGS. 13 to 16 may have configurations similar to the configuration illustrated in FIGS. 2 and 3.

In the semiconductor device 104 illustrated in FIG. 13, the conductive layers 50a to 50d, conductive layers 50h to 50k, and a conductive layer 50m are provided as the conductive layers 50. The conductive layers 50h to 50k are located respectively at the four corner parts of the rectangular second electrode 12. For example, the conductive layers 50h to 50k are located above the corners of the guard ring region GR0 at positions adjacent to the corner parts of the cell region RC. The conductive layer 50m is located in the cell region RC. The conductive layers 50h to 50k and the conductive layer 50m may be surrounded with the second electrode 12.

The conductive layers 50h to 50k and the conductive layer 50m each are connected to at least one of the multiple conductive parts 60 via wiring parts. At least portions of the conductive parts 60 connected to the conductive layers 50 (50h to 50k and 50m) are separated from the conductive layers 50 in directions perpendicular to the Z-direction. The heat can be directed from the conductive part 60 to the conductive layer 50; and the controllability of the temperature can be improved.

For example, there are cases where the electric field is intense at the corner parts of the rectangular shape of the second electrode 12. For example, by including the conductive layers 50h to 50k, the temperature of the semiconductor layer 20 at the peripheries of the conductive layers 50h to 50k can be increased, impact ionization can be suppressed, and the reliability can be increased. For example, by including the conductive layer 50m in the cell region RC, impact ionization in the cell region RC can be suppressed, and the reliability can be increased.

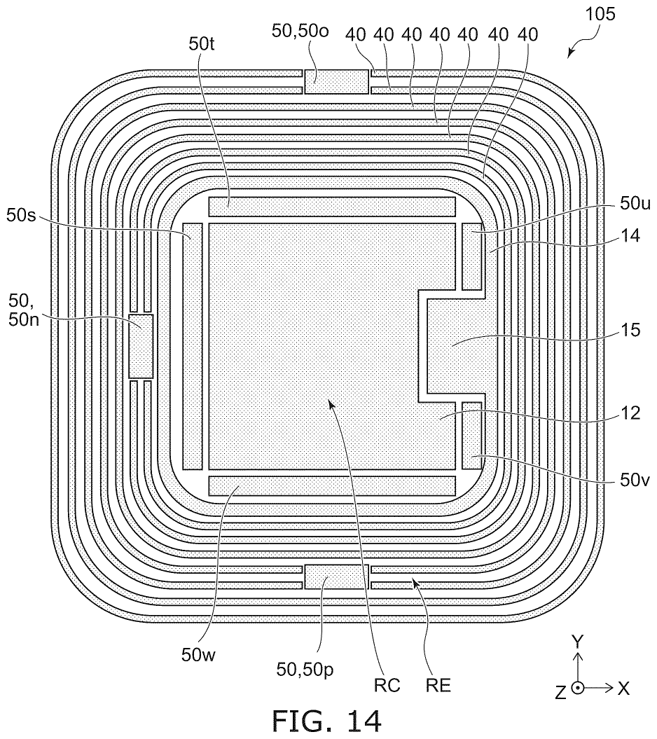

In the semiconductor device 105 illustrated in FIG. 14, conductive layers 50n to 50p and conductive layers 50s to 50w are provided as the conductive layers 50.

The conductive layers 50n to 50p are positioned above the sides of the guard ring regions GR. The conductive layer 50n is positioned above the guard ring regions GR1 and Gr2. The conductive layer 50o is positioned above the guard ring regions GR6 and GR7. The conductive layer 50p is positioned above the guard ring regions GR4 and GR5.

The conductive layers 50s to 50w are arranged along the four sides of the rectangular second electrode 12. The conductive layer 50s extends in the Y-direction parallel to a first side of the second electrode 12. The conductive layer 50t extends in the X-direction parallel to a second side of the second electrode 12. The conductive layers 50u and 50v extend in the Y-direction parallel to a third side of the second electrode 12. The conductive layer 50w extends in the X-direction parallel to a fourth side of the second electrode 12. The conductive layers 50s to 50w are positioned above the guard ring region GR0.

The conductive layers 50n to 50p and the conductive layers 50s to 50w each are connected to at least one of the multiple conductive parts 60 via wiring parts. At least portions of the conductive parts 60 connected to the conductive layers 50 (50n to 50p and 50s to 50w) are separated from the conductive layers 50 in directions perpendicular to the Z-direction. The heat can be directed from the conductive part 60 to the conductive layer 50; and the controllability of the temperature can be improved.

For example, there are cases where the electric field is intense at the boundary vicinity between the cell region RC and the termination region RE. For example, if a current filament extends to the end part of the cell region RC, there are cases where breakdown occurs easily in the cell region RC. In contrast, by locating the conductive layer 50 adjacent to the side of the second electrode 12 as in the conductive layers 50s to 50w, for example, the temperature of the vicinity of the boundary between the cell region RC and the termination region RE can be increased, impact ionization can be suppressed, and the reliability can be increased.

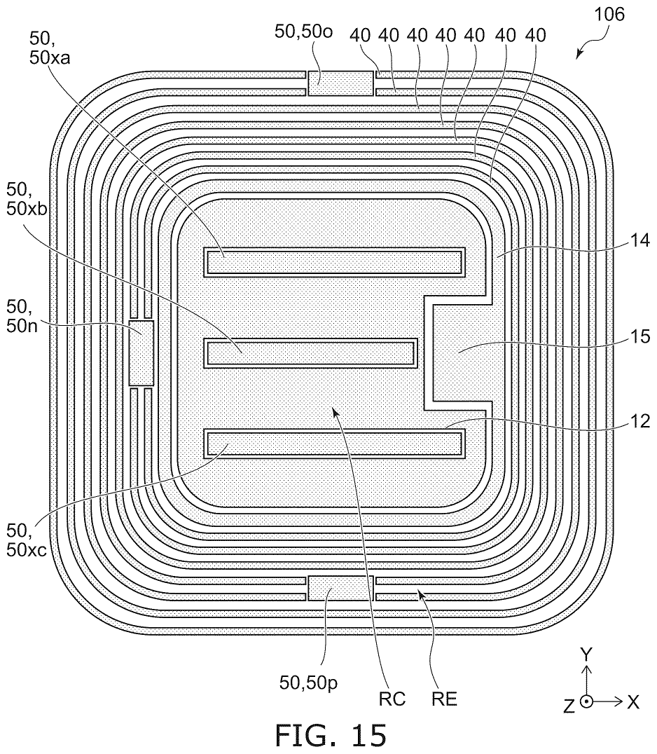

In the semiconductor device 106 illustrated in FIG. 15, the conductive layers 50n to 50p and conductive layers 50xa to 50xc are provided as the conductive layers 50.

The conductive layers 50xa to 50xc each are located in the cell region RC and surrounded with the second electrode 12. The conductive layers 50xa to 50xc extend in the X-direction.

The conductive layers 50n to 50p and the conductive layers 50xa to 50xc each are connected to at least one of the multiple conductive parts 60 via wiring parts. At least portions of the conductive parts 60 connected to the conductive layers 50 (50n to 50p and 50xa to 50xc) are separated from the conductive layers 50 in directions perpendicular to the Z-direction. In the example as well, the heat can be directed from the conductive part 60 to the conductive layer 50; and the controllability of the temperature can be improved.

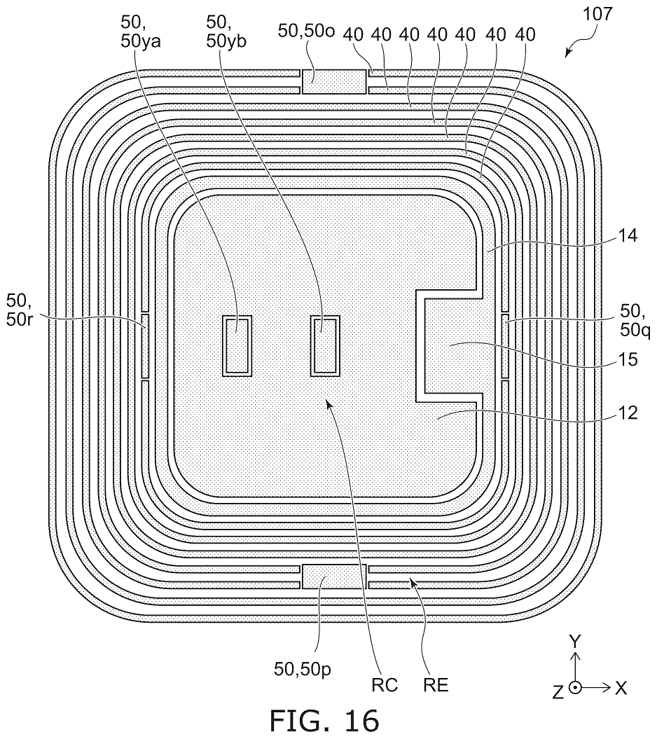

In the semiconductor device 107 illustrated in FIG. 16, the conductive layers 50o to 50r and conductive layers 50ya and 50yb are provided as the conductive layers 50.

The conductive layers 50q and 50r are positioned above linear sides of the guard ring region GR. The conductive layers 50q and 50r are positioned above the guard ring region GR1.

The conductive layers 50ya and 50yb each are located in the cell region RC and surrounded with the second electrode 12. The conductive layers 50ya and 50yb may extend in the Y-direction.

The conductive layers 50o to 50r and the conductive layers 50ya and 50yb each are connected to at least one of the multiple conductive parts 60 via wiring parts. At least portions of the conductive parts 60 connected to the conductive layers 50 (50o to 50r, 50ya, and 50yb) are separated from the conductive layers 50 in directions perpendicular to the Z-direction. In the example as well, the heat can be directed from the conductive part 60 to the conductive layer 50; and the controllability of the temperature can be improved.

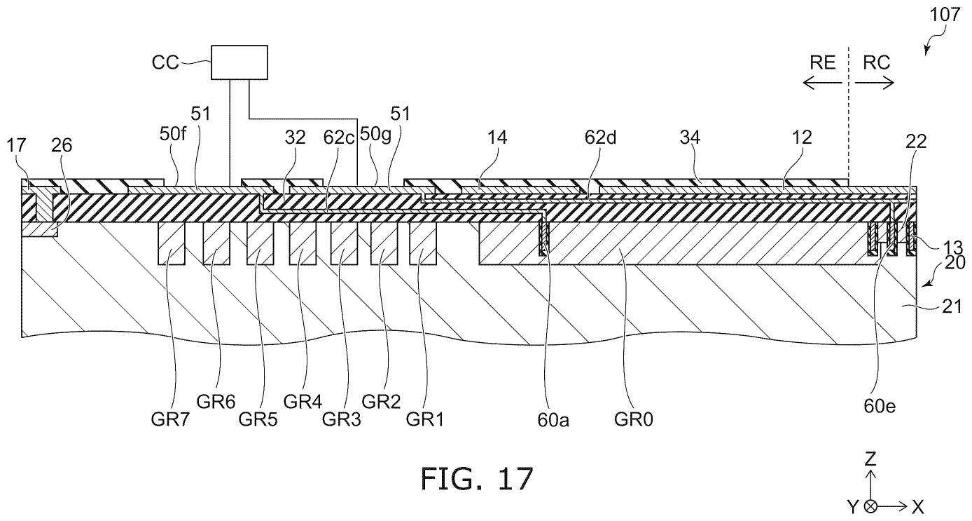

FIG. 17 is a schematic cross-sectional view illustrating another semiconductor device according to an embodiment.

In the semiconductor device 107 illustrated in FIG. 17, the conductive layer 50 includes an application part 51 for applying a voltage to the conductive layer 50. The application part 51 is, for example, an electrode pad exposed in an opening provided in the insulating layer 34. A terminal of a control circuit CC is electrically connected to the application part 51. In the semiconductor device 107, the first electrode 11, the second semiconductor region 22, the third semiconductor region 23, the fourth semiconductor region 24, the fifth semiconductor region 25, and the like are provided, similarly to the previously described semiconductor devices. The semiconductor device 103 may have a configuration similar to the configuration illustrated in FIGS. 2 and 3.”

For example, the control circuit CC can apply a voltage to the conductive part 60 located in the termination region RE via the conductive layer 50. In other words, in the example of FIG. 17, the control circuit CC can apply a voltage to the conductive part 60a via the conductive layer 50f and the wiring part 62c.

For example, the control circuit CC can apply a voltage to the conductive part 60 located in the cell region RC via the conductive layer 50. In other words, the control circuit CC can apply a voltage to the conductive part 60e via the conductive layer 50g and the wiring part 62d.

A voltage of a first polarity (e.g., negative) is applied to the conductive part 60 located in the termination region RE. For example, a voltage of a second polarity (e.g., positive) that is opposite to the first polarity is applied to the conductive part 60 located in the cell region RC. The first and second polarities are referenced to the potential of the second electrode 12. Thus, by applying voltages to the conductive parts 60, for example, the carrier concentration in the semiconductor layer 20 can be controlled. For example, when the potential of the conductive part 60 located in the termination region RE is negative, the discharge of holes in the termination region RE can be promoted. For example, when the potential of the conductive part 60 located in the cell region RC is negative, the discharge of electrons in the cell region RC can be promoted.

Embodiments may include the following configurations.

### Configuration 1

A semiconductor device, comprising:
a first electrode;
a second electrode separated from the first electrode in a first direction;
a semiconductor layer located in a cell region of the device and in a termination region of the device, the termination region surrounding the cell region, the semiconductor layer being positioned between the first electrode and the second electrode in the cell region, the semiconductor layer including
   a first surface proximate to the first electrode,
   a second surface proximate to the second electrode,
   a first semiconductor region located in the cell region and the termination region, the first semiconductor region being of a first conductivity type,
   a second semiconductor region located in the cell region between the first semiconductor region and the second electrode, the second semiconductor region being electrically connected to the second electrode, the second semiconductor region being of a second conductivity type,
   a third semiconductor region located in the cell region between the second semiconductor region and the second electrode, the third semiconductor region being electrically connected to the second electrode, the third semiconductor region being of the first conductivity type, and
   a plurality of guard ring regions located in the termination region at the second surface side of the first semiconductor region, the plurality of guard ring regions surrounding the cell region, the plurality of guard ring regions being of the second conductivity type;
a third electrode facing the second semiconductor region via a first insulating part;
a first conductive part facing at least one of the plurality of guard ring regions via a second insulating part; and
a first conductive layer positioned above the semiconductor layer, the first conductive layer being separated from at least a portion of the first conductive part in a direction perpendicular to the first direction, the first conductive layer being electrically connected to the first conductive part.

### Configuration 2

The device according to Configuration 1, further comprising:
a wiring part connecting the first conductive part and the first conductive layer.

### Configuration 3

The device according to Configuration 1 or 2, wherein
a thermal conductivity of the first conductive part is greater than a thermal conductivity of the third electrode.

### Configuration 4

The device according to any one of Configurations 1 to 3 wherein
the first conductive layer is positioned above a portion of at least one of the plurality of guard ring regions.

### Configuration 5

The device according to any one of Configurations 1 to 4 wherein
at least one of the plurality of guard ring regions surrounds the cell region and includes a corner part,
the corner part is curved, and
the first conductive layer is positioned above the corner part of the at least one of the plurality of guard ring regions.

### Configuration 6

The device according to any one of Configurations 1 to 5, wherein
the plurality of guard ring regions include an inner guard ring region, and an outer guard ring region surrounding the inner guard ring region, and
the first conductive layer is positioned above the inner guard ring region.

### Configuration 7

The device according to any one of Configurations 1 to 5 wherein
the plurality of guard ring regions include an innermost guard ring region most proximate to the cell region among the plurality of guard ring regions, and
the first conductive layer is positioned above the innermost guard ring region.

### Configuration 8

The device according to any one of Configurations 1 to 3 wherein
the first conductive layer is located in the cell region.

### Configuration 9

The device according to any one of Configurations 1 to 7 wherein
the first conductive layer is arranged along an outer edge of the second electrode.

### Configuration 10

The device according to any one of Configurations 1 to 7 wherein
the second electrode has a rectangular shape, and
the first conductive layer is located at a corner part of the rectangular shape of the second electrode.

### Configuration 11

The device according to any one of Configurations 1 to 10, further comprising:
a second conductive part facing the second semiconductor region via a third insulating part,
the first conductive layer being separated from at least a portion of the second conductive part in a direction perpendicular to the first direction,
the first conductive layer being electrically connected to the second conductive part.

### Configuration 12

The device according to any one of Configurations 1 to 10, further comprising:
a second conductive part facing the second semiconductor region via a third insulating part; and
a second conductive layer positioned above the semiconductor layer,
the second conductive layer being separated from at least a portion of the second conductive part in a direction perpendicular to the first direction,
the second conductive layer being electrically connected to the second conductive part.

### Configuration 13

The device according to any one of Configurations 1 to 12, further comprising:
a third conductive part facing at least one of the plurality of guard ring regions via a fourth insulating part,
the first conductive layer being separated from at least a portion of the third conductive part in a direction perpendicular to the first direction,
the first conductive layer being electrically connected to the third conductive part.

### Configuration 14

The device according to any one of Configurations 1 to 12, further comprising:
a third conductive part facing at least one of the plurality of guard ring regions via a fourth insulating part; and
a third conductive layer positioned above the semiconductor layer,
the third conductive layer being separated from at least a portion of the third conductive part in a direction perpendicular to the first direction,
the third conductive layer being electrically connected to the third conductive part.

### Configuration 15

The device according to any one of Configurations 1 to 14, wherein
the plurality of guard ring regions include an innermost guard ring region most proximate to the cell region among the plurality of guard ring regions, and
the first conductive part is positioned above the innermost guard ring region.

### Configuration 16

The device according to any one of Configurations 1 to 15, wherein
the first conductive layer does not overlap the first conductive part in the first direction.

### Configuration 17

The device according to any one of Configurations 1 to 16, comprising:
a plurality of conductive layers including the first conductive layer,
each of the plurality of conductive layers being electrically connected respectively to a conductive part,
the conductive part facing the second semiconductor region or at least one of the plurality of guard ring regions via an insulating part,
the semiconductor layer being rectangular,
at least one of the plurality of conductive layers being located above each of four corner parts of the semiconductor layer.

### Configuration 18

The device according to Configuration 2, wherein
the wiring part includes a plurality of wiring layers.

### Configuration 19

The device according to Configuration 2, wherein
a thermal conductivity of the wiring part is different from a thermal conductivity of the first conductive layer.

### Configuration 20

The device according to any one of Configurations 1 to 19, wherein
a control circuit is configured to apply a voltage to the first conductive part via the first conductive layer.

According to embodiments, a semiconductor device can be provided in which the controllability of the temperature can be improved.

According to embodiments above, the impurity concentration in each semiconductor region can be measured by, for example, SIMS (secondary ion mass spectrometry). The relative levels of the impurity concentrations between the semiconductor regions can be confirmed using, for example, a SCM (scanning capacitance microscope). When both an impurity that forms donors and an impurity that forms acceptors are included in one region, the impurity concentration level may be the net impurity concentration level after the impurities have canceled.

In this specification, being “electrically connected” includes not only the case of being connected in direct contact, but also the case of being connected via another conductive member, etc. The “same” or “equal” includes not only exactly the same or equal, but also substantially the same or substantially equal. For example, the scope of “same” or “equal” includes cases including differences caused by manufacturing process fluctuation. In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first electrode;
a second electrode separated from the first electrode in a first direction;
a semiconductor layer located in a cell region of the device and in a termination region of the device, the termination region surrounding the cell region, the semiconductor layer being positioned between the first electrode and the second electrode in the cell region, the semiconductor layer including
a first surface proximate to the first electrode,
a second surface proximate to the second electrode,
a first semiconductor region located in the cell region and the termination region, the first semiconductor region being of a first conductivity type,
a second semiconductor region located in the cell region between the first semiconductor region and the second electrode, the second semiconductor region being electrically connected to the second electrode, the second semiconductor region being of a second conductivity type,
a third semiconductor region located in the cell region between the second semiconductor region and the second electrode, the third semiconductor region being electrically connected to the second electrode, the third semiconductor region being of the first conductivity type, and
a plurality of guard ring regions located in the termination region at the second surface side of the first semiconductor region, the plurality of guard ring regions surrounding the cell region, the plurality of guard ring regions being of the second conductivity type;
a third electrode facing the second semiconductor region via a first insulating part;
a first conductive part facing at least one of the plurality of guard ring regions via a second insulating part; and
a first conductive layer positioned above the semiconductor layer, the first conductive layer being separated from at least a portion of the first conductive part in a direction perpendicular to the first direction, the first conductive layer being electrically connected to the first conductive part.

2. The device according to claim 1, further comprising:
a wiring part connecting the first conductive part and the first conductive layer.

3. The device according to claim 1, wherein
a thermal conductivity of the first conductive part is greater than a thermal conductivity of the third electrode.

4. The device according to claim 1, wherein
the first conductive layer is positioned above a portion of at least one of the plurality of guard ring regions.

5. The device according to claim 1, wherein
at least one of the plurality of guard ring regions surrounds the cell region and includes a corner part,
the corner part is curved, and
the first conductive layer is positioned above the corner part of the at least one of the plurality of guard ring regions.

6. The device according to claim 1, wherein
the plurality of guard ring regions include an inner guard ring region, and an outer guard ring region surrounding the inner guard ring region, and
the first conductive layer is positioned above the inner guard ring region.

7. The device according to claim 1, wherein
the plurality of guard ring regions include an innermost guard ring region most proximate to the cell region among the plurality of guard ring regions, and
the first conductive layer is positioned above the innermost guard ring region.

8. The device according to claim 1, wherein
the first conductive layer is located in the cell region.

9. The device according to claim 1, wherein
the first conductive layer is arranged along an outer edge of the second electrode.

10. The device according to claim 1, wherein
the second electrode has a rectangular shape, and
the first conductive layer is located at a corner part of the rectangular shape of the second electrode.

11. The device according to claim 1, further comprising:
a second conductive part facing the second semiconductor region via a third insulating part,
the first conductive layer being separated from at least a portion of the second conductive part in a direction perpendicular to the first direction,
the first conductive layer being electrically connected to the second conductive part.

12. The device according to claim 1, further comprising:
a second conductive part facing the second semiconductor region via a third insulating part; and
a second conductive layer positioned above the semiconductor layer,
the second conductive layer being separated from at least a portion of the second conductive part in a direction perpendicular to the first direction,
the second conductive layer being electrically connected to the second conductive part.

13. The device according to claim 1, further comprising:
a third conductive part facing at least one of the plurality of guard ring regions via a fourth insulating part,
the first conductive layer being separated from at least a portion of the third conductive part in a direction perpendicular to the first direction,
the first conductive layer being electrically connected to the third conductive part.

14. The device according to claim 1, further comprising:
a third conductive part facing at least one of the plurality of guard ring regions via a fourth insulating part; and
a third conductive layer positioned above the semiconductor layer,
the third conductive layer being separated from at least a portion of the third conductive part in a direction perpendicular to the first direction,
the third conductive layer being electrically connected to the third conductive part.

15. The device according to claim 1, wherein
the plurality of guard ring regions include an innermost guard ring region most proximate to the cell region among the plurality of guard ring regions, and
the first conductive part is positioned above the innermost guard ring region.

16. The device according to claim 1, wherein
the first conductive layer does not overlap the first conductive part in the first direction.

17. The device according to claim 1, comprising:
a plurality of conductive layers including the first conductive layer,
each of the plurality of conductive layers being electrically connected respectively to a conductive part,
the conductive part facing the second semiconductor region or at least one of the plurality of guard ring regions via an insulating part,
the semiconductor layer being rectangular,
at least one of the plurality of conductive layers being located above each of four corner parts of the semiconductor layer.

18. The device according to claim 2, wherein
the wiring part includes a plurality of wiring layers.

19. The device according to claim 2, wherein
a thermal conductivity of the wiring part is different from a thermal conductivity of the first conductive layer.

20. The device according to claim 1, wherein
a control circuit is configured to apply a voltage to the first conductive part via the first conductive layer.
